(19) United States
(12) Patent Application Publication
(10) Pub. No.: US 2010/0268492 A1
(43) Pub. Date: Oct. 21, 2010

(54) Battery cell voltage measurement device

(75) Inventor: Kimihiro Matsuura, Makinohara (JP)

Correspondence Address: EDWARDS ANGELL PALMER & DODGE LLP, P.O. BOX 55874, BOSTON, MA, 02205, US

(73) Assignee: Yazaki Corporation, Tokyo (JP)

(21) Appl. No.: 12/662,318

(22) Filed: Apr. 12, 2010

(30) Foreign Application Priority Data
Apr. 15, 2009 (JP) 2009-098808

(51) Int. Cl. G01R 31/36

(52) U.S. Cl. 702/63; 324/72

(57) ABSTRACT

A battery cell voltage measurement device for a battery pack constructed by battery cells (E1, E2, . . . , En) includes measurement-and-processing blocks (11 to 1n) connected to each other via communication lines (CL1, CL2). The blocks measure a terminal voltage of corresponding each of the battery cells, monitor battery cell status, generate a signal indicative of a monitoring result of the battery cell, perform voltage level shifting of the signal on a per-block basis, and transmit the level-shifted signal to a neighboring block via the line (CL2). A controller (CON) connected to one of the blocks via the line controls the blocks, receives the level-shifted signal from the block connected thereto. Resistors (Ra, Rb) for protection provided on the communication lines (CL1, CL2) protect circuit components of the blocks from malfunction when a potential difference occurs between the blocks.

### CROSS REFERENCE TO RELATED APPLICATION

The priority application Japan Patent Application No. 2009-098808 upon which this patent application is based is hereby incorporated by reference.

### BACKGROUND OF THE INVENTION

1. Field of the Invention

The present invention relates to a device that measures terminal voltage of battery cells of a battery pack.

2. Description of the Related Art

FIG. 4 is a block diagram of a conventional battery cell voltage measurement device. A battery pack B is a DC power source for use in an electrical vehicle and a hybrid vehicle. The battery pack B is constructed by a plurality of series-connected battery cells E1, E2, . . . , En that may have a terminal voltage of five volts 5V. The battery pack B may supply high-voltage DC (direct-current) power of 250 to 300 volts. Different terminal voltages, i.e., voltages of terminals of the battery cells, may decrease reliability of the battery pack as a whole and accordingly it is necessary to detect the terminal voltage of each battery cell and equalize the terminal voltages of all the battery cells.

A battery cell voltage measurement unit 1 is connected to the battery pack B that is yet to be mounted in a vehicle and is configured to measure the terminal voltages of the battery cells E1, E2, . . . , En, monitor states of the battery cells, and equalize the terminal voltages of all the battery cells.

Cell status monitoring of the state of the battery cells includes (a) monitoring whether the battery cell is in a normal state or in an abnormal state, (b) monitoring whether the battery cell is in a state of overcharge or in a state of over-discharge, and (c) generating an indication signal indicative of a result of monitoring in accordance with the identified states of the battery cell. With respect to voltage level equalization of the terminal voltages, a capacitor may be used to perform charge-pump-type equalization, in which a charge of a battery cell whose voltage between both ends is high is shifted to a battery cell whose voltage between both ends is low, or perform discharge-type equalization for a battery cell whose voltage between both ends is high so that the high both-end voltage becomes equal to that of the battery cell whose terminal voltage is the lowest. It is assumed in this document that discharge-type equalization is employed. The discharge-type technique is known and therefore is not illustrated in the attached drawings.

The battery cell voltage measurement unit 1 includes a plurality of measurement-and-processing blocks 11, 12, . . . , 1n, an isolating part INS, and a controller CON. The measurement-and-processing blocks 11, 12, . . . , 1n has the same configuration and are connected to a positive terminal and a negative terminal of each of the battery cells E1, E2, . . . , En via corresponding each of connecting terminals VIN (bottom), VIN12, VIN23, . . . , VIN (top). The measurement-and-processing blocks 11, 12, . . . , 1n each have an integrated circuit IC having the same configuration.

Referring to FIG. 1, the measurement-and-processing block 11 is configured to measure a terminal voltage of a lowermost battery cell E1. The measurement-and-processing block 11 includes a supply terminal connected to a positive terminal of the battery cell E1 via a current limiting resistor R1 and a connecting terminal VIN12; a GND terminal connected to a negative terminal of the battery cell E1 via a connecting terminal VIN (bottom); and two voltage measurement terminals connected to both terminals of the battery cell E1 via discharging resistors R2, R3 and connecting terminals VIN12, VIN (bottom), respectively. A capacitor C1 is connected to the two voltage measurement terminals.

The measurement-and-processing block 11 performs internal level-shift communication with the measurement-and-processing block 12 via communication lines CL1, CL2. The measurement-and-processing block 12 is configured to measure the terminal voltage of the battery cell E2 that is connected to the positive terminal of the battery cell E1 and performs the cell status monitoring and voltage equalization. The measurement-and-processing block 11 also performs communications with the controller CON via the isolating part INS that may include a light emitting device and a light receiving device.

The measurement-and-processing blocks 12 to 1n-1 similar to the measurement-and-processing block 11 are each configured to measure a terminal voltage of the corresponding one of the battery cells and performs cell status monitoring and voltage equalization. The measurement-and-processing blocks 12 to 1n-1 also perform voltage level shifting to shift their own voltage with respect to their neighboring higher-voltage-side measurement-and-processing block on a per-block basis, and perform internal level-shift communications via the communication lines CL1, CL2. The uppermost measurement-and-processing block 1n is configured to measure the terminal voltage of the uppermost battery cell En and performs internal level-shift communication with the lower-voltage-side measurement-and-processing block 1n-1.

The controller CON may include a microcontroller. The controller CON is connected to the measurement-and-processing blocks 11 via the isolating part INS. The controller CON receives the indication signal indicative of the result of monitoring originating from the measurement-and-processing blocks 11 to 1n, monitors the state of the battery cells, identifies the battery cell having the lowest terminal voltage, and transmits an instruction signal to the measurement-and-processing blocks 11 to 1n, the instruction signal instructing the measurement-and-processing blocks 11 to 1n to make the remaining battery cells discharged until their terminal voltage becomes equal to the terminal voltage of the battery cell having the lowermost voltage so that the terminal voltages of all of the battery cells are equalized.

Also, the controller CON may transmit to an external device various information including the terminal voltage of the battery pack B after the terminal voltage equalization.

Referring to FIG. 5, there is shown a block diagram illustrating an exemplary internal configuration of the measurement-and-processing block. The measurement-and-processing block has a supply terminal VPP connected to the positive terminal of the battery cell via a current limiting resistor R1; a GND terminal VEE connected to the negative terminal of the battery cell; two voltage measurement terminals VD and VE connected to the positive terminal and the negative terminal of the battery cell, respectively, via the discharging resistors R2 and R3; communication input terminals DIN1 and DIN2; and communication output terminals DOUT1 and DOUT2.

The measurement-and-processing block further includes: a measurement-and-processing part 111 that is connected to the supply terminal VPP, the GND terminal VEE, and the voltage measurement terminals VD, VE; a receiving part 112 to which an indication signal from the controller CON is input via the communication input terminal DIN1; a voltage level shifter 113; and a transmitting part 114.

The measurement-and-processing part 111 is configured to measure the terminal voltage of the battery cell, monitor the state of the battery cell, output the indication signal indicative of the result of monitoring, and perform terminal voltage equalization.

The receiving part 112 is configured to transmit the indication signal to the measurement-and-processing part 111.

The voltage level shifter 113 performs voltage level shift for the indication signal that has been received by the receiving part 112 so that content of the indication signal conforms to a higher-voltage-side measurement-and-processing block.

The transmitting part 114 is configured to output the indication signal, which has been level-shifted by the voltage level shifter 113 to be in conformance with the higher-voltage-side measurement-and-processing block, on the communication output terminal DOUT1 for signal transmission.

The measurement-and-processing block still further includes: a receiving part 115; a voltage level shifter 116; and a transmitting part 117.

The receiving part 115 is configured to receive a signal from the higher-voltage-side measurement-and-processing block via the communication input terminal DIN2.

The voltage level shifter 116 performs voltage level shift for the signal received by the receiving part 115 so that content of the signal conforms to the lower-voltage-side measurement-and-processing block.

The transmitting part 117 is configured to output the signal, which has been level-shifted by the voltage level shifter 116 to be in conformance with the lower-voltage-side measurement-and-processing block, on the communication output terminal DOUT2 for signal transmission. The transmitting part 117 adds the signal indicative of the result of monitoring that has been sent from the measurement-and-processing part 111 to the signal sent from the higher-voltage-side measurement-and-processing block, and outputs the obtained signal on the communication output terminal DOUT2.

Referring to FIG. 6, there is shown a circuit diagram for explanation of an internal level-shift communication. The FIG. 6 shows circuit configurations of the transmitting part 114 of the measurement-and-processing block 11 and the receiving part 112 of the measurement-and-processing block 12.

The transmitting part 113 of the measurement-and-processing block 11 includes a supply terminal VPP (IC1), zener diodes ZD1, ZD2, ZD3, ZD4, ZD5, a resistor R13, and an inverter INV1.

The supply terminal VPP (IC1) is connected to the connecting terminal VIN12 via the current limiting resistor R1. The zener diode ZD1 is connected to the GND terminal VEE (IC1) that is connected to the connecting terminal VIN (bottom). The zener diode ZD2 is connected between the supply terminal VPP (IC1) and the IC internal electrical power source VH (IC1). The zener diode ZD3 that is connected between the IC internal electrical power source VH (IC1) and the GND terminal VEE (IC1); an inverter INV1 whose input terminal is connected to an output of the voltage level shifter 113, the inverter INV1 being powered by the voltage between the supply terminal VPP (IC1) and the IC internal electrical power source VH (IC1); The zener diode ZD4 and the resistor R13 are series-connected between the output terminal of the inverter INV1 and the communication output terminal DOUT1 (IC1). The zener diode ZD5 is connected between the supply terminal VPP (IC1) and the communication output terminal DOUT1 (IC1).

A voltage of the IC internal electrical power source VH (IC1) is set to be a voltage obtained by subtracting a predetermined voltage (for example, 6V) from a supply voltage of the supply terminal VPP (IC1).

The receiving part 112 of the measurement-and-processing block 12 includes a resistor R11, an inverter INV2, and zener diodes ZD6, ZD7, ZD8.

The resistor R11 is connected between the IC internal electrical power source VL (IC2) and the communication input terminal DIN1 (IC1). The inverter INV2 has an input terminal that is connected to the communication input terminal DIN1 (IC1) via the resistor R12, and an output terminal that is connected to an input terminal of the voltage level shifter 113. The zener diodes ZD6 and ZD7 are series-connected with reversed polarity between the IC internal electrical power source VL (IC2) and the input terminal of the inverter INV2. The zener diode ZD8 is connected between the input terminal of the inverter INV2 and the GND terminal VEE (IC2).

Voltage of the IC internal electrical power source VL (IC2) is set to be a voltage obtained by a supply voltage of the supply terminal VPP (IC2) minus a predetermined voltage (for example, six volts).

The communication output terminal DOUT1 (IC1) of the measurement-and-processing block 11 is connected to a communication input terminal DINT (IC2) of the measurement-and-processing block 12 via the communication line CL2. Similarly, the communication output terminal DOUT2 (IC2) of the measurement-and-processing block 12 is connected to the communication input terminal DIN2 (IC1) of the measurement-and-processing block 11 via the communication line CL1.

The conventional measurement-and-processing block is disclosed for example in Japanese Patent Application Laid-Open Publication No. 2001-307782.

In the battery cell voltage measurement device with the above-described configuration, an inrush current may flow in the measurement-and-processing block at the time when battery cell voltage measurement unit 1 is connected to the battery pack B, or difference occurs in current consumption among the measurement-and-processing blocks. When a potential difference increases between the GND terminal of the higher-voltage-side measurement-and-processing block and the supply terminal of a neighboring lower-voltage-side measurement-and-processing block, for example when a potential difference is increased between the supply voltage of the supply terminal VPP (IC1) of the measurement-and-processing block 11 and the voltage occurring in a communication input terminal DINT (IC2) of the measurement-and-processing block 12, a withstand voltage of a zener diode ZD5 for protection purpose may be exceeded and the zener diode ZD5 may fail to properly operate. Also, even when the withstand voltage is large, excessively large current may flow in an input of the communication circuit, causing the circuit element to fail to properly operate.

### SUMMARY OF THE INVENTION

In view of the above-identified drawbacks, an object of the present invention is to provide a battery cell voltage measurement device that is capable of protecting circuit elements from malfunction and destruction when a potential difference occurs between a plurality of the measurement-and-processing blocks.

To attain the above objective, there is provided a battery cell voltage measurement device for a battery pack constructed of battery cells (E1, E2, . . . , En) that are connected in series with each other, including: measurement-and-processing blocks (11 to 1n) that are connected to each other via a communication line (CL1, CL2), provided for corresponding each of the battery cells, and configured to measure a terminal voltage of the corresponding each of the battery cells, monitor a state of the corresponding each of the battery cells, generate an indication signal indicative of a result of monitoring of the corresponding each of the battery cells, and perform voltage level shifting of the indication signal on per-block basis, and transmit the voltage-level-shifted indication signal to a neighboring one of the measurement-and-processing blocks via the communication line (CL2); a controller (CON) connected to one of the measurement-and-processing blocks via the communication line so as to control the measurement-and-processing blocks, and configured to receive the voltage-level-shifted indication signal sent from the measurement-and-processing block connected to the controller (CON); and a resistor (Ra, Rb) for protection provided on the communication line (CL1, CL2), the resistor for protection being configured to protect circuit elements of a communication circuit of the measurement-and-processing blocks from malfunction in a case where a potential difference occurs in a connection between the measurement-and-processing blocks adjacent to each other.

Since the resistor for protection is provided on the communication line over which the signal indicative of the result of monitoring of the state of each of the battery cells among the measurement-and-processing blocks, malfunction of the circuit elements of the communication circuit between the measurement-and-processing blocks can be avoided when a potential difference occurs in the connection of communication between the neighboring measurement-and-processing blocks connected via the communication line. Also, since all that is needed is to interposedly provide the resistor on the communication line, protection of the circuit elements constituting the communication circuit can be achieved in a simple manner with reduced cost.

Preferably, the battery cell voltage measurement device further includes a diode (D1) for voltage clamping provided between a supply terminal (VPP) and an output terminal of an output element (INV1) of the measurement-and-processing block that sends the indication signal to the neighboring measurement-and-processing block connected via the communication line (CL1, CL2).

Since the diode for voltage clamping is provided between the supply terminal and the output terminal of the measurement-and-processing block used to transmit the signal to the neighboring measurement-and-processing block connected via the communication line, destruction of the output element of the communication circuit is prevented when the potential difference occurs between the measurement-and-processing blocks.

Preferably, the battery cell voltage measurement device further includes a diode (Da, Db) for reverse current prevention is provided in series with the resistor (Ra, Rb) for protection so as to prevent a reverse current in a case where a voltage at a communication terminal of the measurement-and-processing block of a lower-voltage side becomes larger than a voltage of a communication terminal of the measurement-and-processing block of a higher-voltage side connected via the communication line (CL1, CL2) to the lower-voltage side.

Since the diode for reverse current prevention is provided in series with the resistor for protection, even when the voltage appearing at the communication terminal of the lower-voltage-side measurement-and-processing block connected via the communication line becomes larger than the voltage appearing at the communication terminal of the higher-voltage-side measurement-and-processing block, a voltage exceeding the withstand voltage is not applied to the circuit element of the communication circuit of the higher-voltage-side measurement-and-processing block from the side of the lower-voltage-side measurement-and-processing block, and thus destruction of the components is effectively prevented.

Preferably, the diode (Da, Db) for reverse current prevention of the battery cell voltage measurement device is provided closer to the output element of the measurement-and-processing block than the resistor for protection is.

Since the diode for reverse current protection is inserted in a region near to the output element of the measurement-and-processing block, it is possible to ensure that a stray capacitance of the diode does not seriously affect communication speed when a current for the signal transmitted over the communication line is designed to be small.

Preferably, the battery cell voltage measurement device further includes a zener diode (ZD9) for protection is provided between the communication output terminal and a GND terminal of the measurement-and-processing block.

Since the zener diode for protection is provided between the GND terminal and the communication output terminal of the measurement-and-processing block, the voltage is suppressed so that it does not rise to a voltage level at which an overcurrent flows in the diode for voltage clamping when the voltage appearing at the communication output terminal is risen, so that the diode for voltage clamping can be protected against destruction.

Preferably, the controller (CON) is configured to output an instruction signal for equalizing the terminal voltages of all the battery cells to the measurement-and-processing block (11) connected to the controller (CON), the measurement-and-processing blocks (11 to 1n) in turn perform voltage level shifting of the received instruction signal on a per-block basis, and transmit a voltage-level-shifted instruction signal to respective neighboring measurement-and-processing blocks via the communication line (CL1).

The above construction allows the battery cell voltage measurement device to perform, in addition to cell status monitoring of the battery cells on a per-cell basis, equalization of the terminal voltages of all the battery cells.

It should be noted that the parenthesized reference numerals in the foregoing basically corresponds to those assigned to elements or components that will appear in the following detailed description of the invention. However, these reference in the foregoing do not define or limit the scope of this invention.

### BRIEF DESCRIPTION OF THE DRAWINGS

The above and other objects and advantages of the present invention will be apparent upon reading of the following detailed description, taken in conjunction with the following accompanying drawings, in which like reference numerals represent corresponding parts throughout:

FIG. 1 is a circuit diagram of a battery cell voltage measurement device according to a first embodiment of the present invention.

FIG. 2 is a circuit diagram of a battery cell voltage measurement device according to a second embodiment of the present invention.

FIG. 3 is a circuit diagram of a battery cell voltage measurement device according to a third embodiment of the present invention.

FIG. 4 is a block diagram of a conventional battery cell voltage measurement device.

FIG. 5 is a block diagram illustrating an internal configuration of a measurement-and-processing block of the battery cell voltage measurement device of FIG. 4.

FIG. 6 is a circuit diagram for explanation of internal level-shift communication in the battery cell voltage measurement device of FIG. 4.

### DETAILED DESCRIPTION OF THE INVENTION

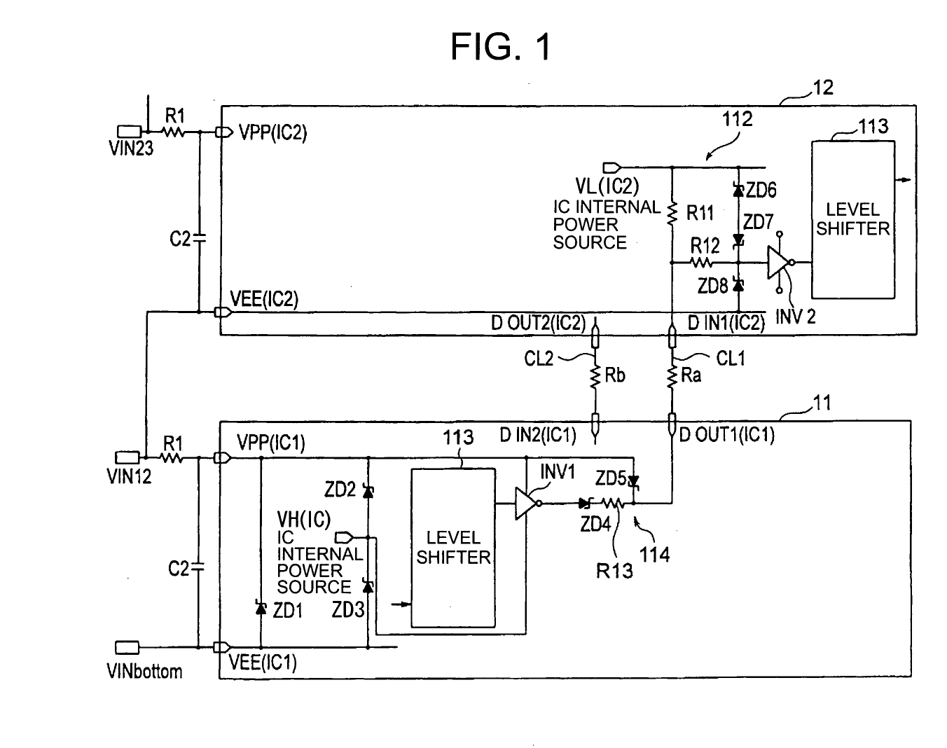

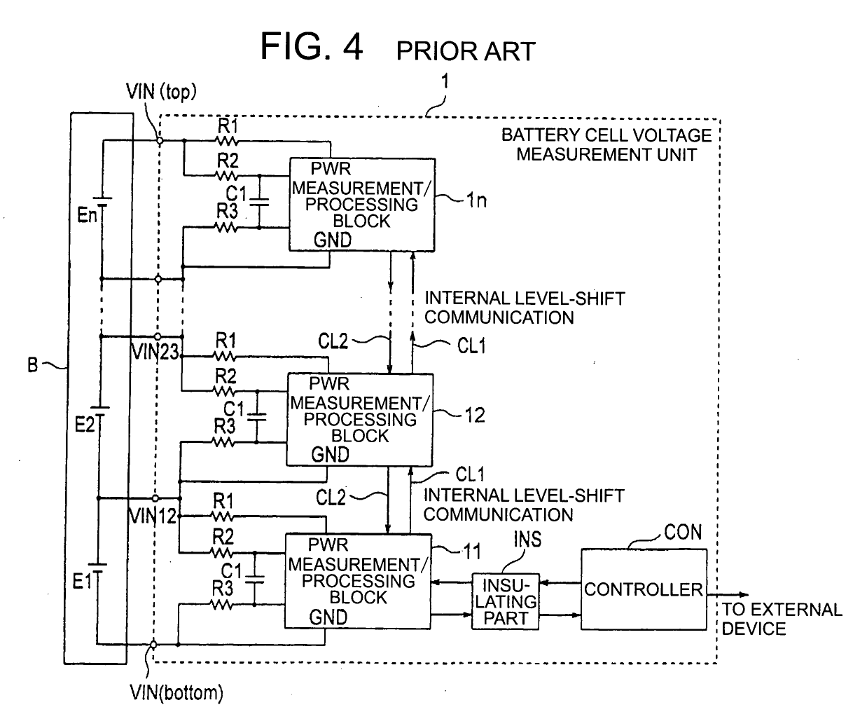

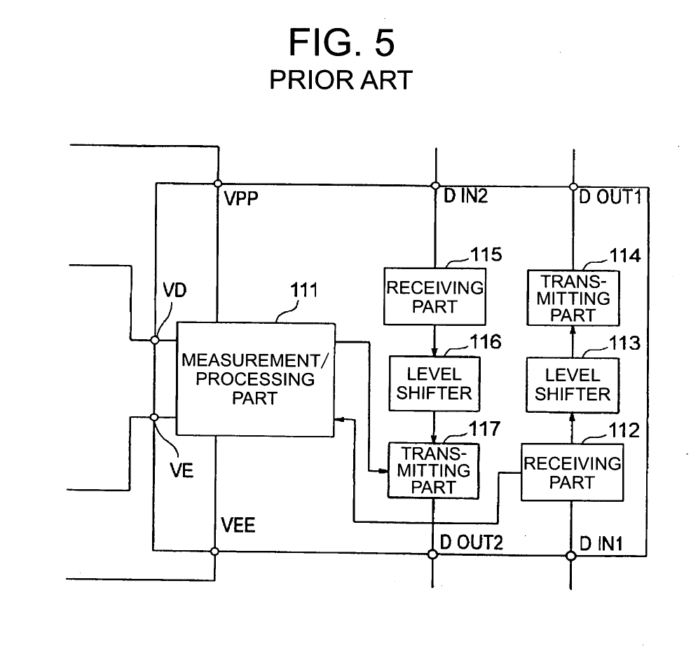

In the following description of exemplary embodiments of the present invention, reference is made to FIGS. 1 to 6 in which is shown by way of illustration specific exemplary embodiments in which A device for measuring a voltage of a battery cell, i.e., a “battery cell voltage measurement device” of the present invention may be practiced. In the exemplary embodiments, the battery cell voltage measurement device of the present invention has a basic configuration substantially identical with such a known one as is shown in FIGS. 4 and 5, which has been disclosed in the introductory discussion of the prior art, and therefore the already discussed features are not restated in detail in the following exemplary embodiments.

### First Embodiment

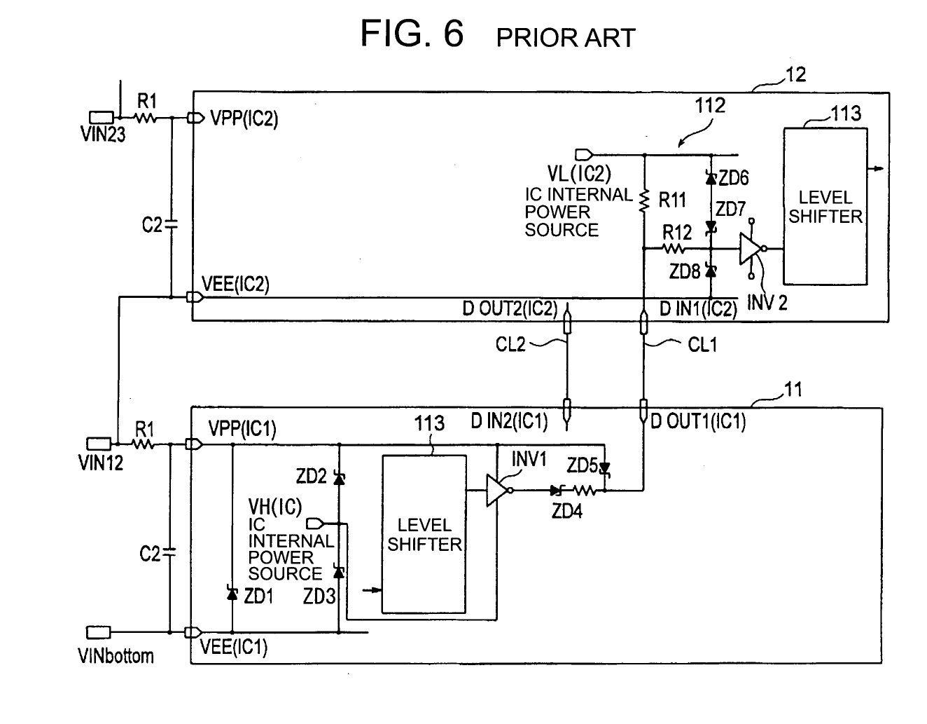

Referring to FIG. 1, there is shown a circuit diagram of the battery cell voltage measurement device according to a first embodiment of the present invention. In the first embodiment shown in FIG. 1, circuit configurations of measurement-and-processing blocks 11 and 12 may generally be the same as the conventional circuit configurations discussed with reference to FIG. 6.

The circuit configurations of these blocks 11 and 12 differ from the conventional ones of FIG. 6 in that a resistor Ra for protection is provided on a communication line CL1 that connects a communication output terminal DOUT1 (an integrated circuit IC1) of the measurement-and-processing block 11 to a communication input terminal DIN1 (IC2) of the measurement-and-processing block 12.

The circuit configurations of these blocks 11 and 12 also differ from the above conventional ones in that a resistor Rb for protection is provided on a communication line CL2 that connects a communication output terminal DOUT2 (IC2) of the measurement-and-processing block 12 to a communication input terminal DIN2 (IC1) of the measurement-and-processing block 11.

In the configuration of FIG. 1, the resistors Ra, Rb for protection are provided on the communication lines CL1, CL2 for use in internal level-shift communication between the measurement-and-processing blocks, respectively. By, virtue of interposition of the resistors Ra, Rb configuration between the communication input/output terminals, even when the potential difference occurs between the measurement-and-processing blocks, a voltage is applied to the resistor Ra, Rb and as a result it is possible to prevent a voltage exceeding a rated voltage of the IC1 and IC2 circuits from being applied to the communication input/output terminals (i.e., the communication input terminals and communication output terminals) of the measurement-and-processing blocks. Thus, it is possible to avoid malfunction of the communication circuits and circuit elements that constitute the communication circuits caused by a voltage exceeding a withstand voltage being applied to the circuit elements.

According to the first embodiment of the present invention, it is appreciated that the circuit elements of the communication circuits can be protected against malfunction and destruction in a case where the potential difference occurs between the measurement-and-processing blocks by simply interposedly providing the resistors for protection between the communication output terminals and the communication input terminal of the measurement-and-processing block. This obviously is a cost-effective solution to protection of the circuit elements.

### Second Embodiment

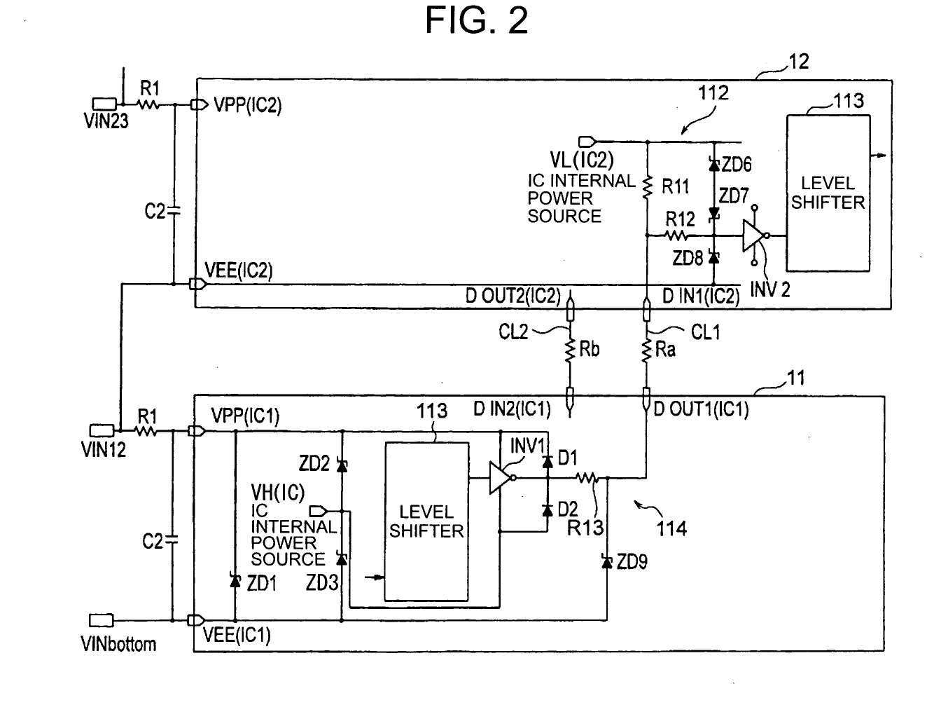

Referring now to FIG. 2, there is shown a circuit diagram of a battery cell voltage measurement device according to a second embodiment of the present invention. An internal circuit configuration of the measurement-and-processing block 11 of the second embodiment differs from that shown in FIG. 1 in that zener diodes ZD4 and ZD5 of FIG. 1 are not provided in FIG. 2. Instead, a diode D1 for voltage clamp is connected between a supply terminal VPP (IC1) and an output terminal of an inverter INV1, a diode D2 for voltage clamp is connected between a GND terminal VEE (IC1) and the output terminal of the inverter INV1, and a zener diode ZD9 for protection is connected between the communication output terminal DOUT1 (IC1) and the GND terminal VEE(IC1).

In the circuit configuration of FIG. 2, when a voltage at the communication output terminal DOUT1 (IC1) of the measurement-and-processing block 11 becomes larger than a voltage obtained by adding a supply voltage of the supply terminal VPP (IC1) of the measurement-and-processing block 11 to a forward drop voltage of the diode D1, then the diode D1 conducts and current flows, so that a potential of the output terminal of the inverter INV1 is clamped to the voltage obtained by adding the supply voltage of the supply terminal VPP (IC1) to the forward drop voltage of the diode D1. When the diode D1 conducts, a current that flows in the diode D1 is placed under current limiting due to existence of the resistors Ra and R13.

Also, when the voltage flowing in the communication output terminal DOUT1 (IC1) becomes large, the zener diode ZD9 limits the voltage so that the voltage does not exceed a voltage level at which overcurrent may flow in the diode D1 for voltage clamp. In this manner, the diode D1 can be protected against destruction due to overcurrent.

Thus, when the potential difference between the measurement-and-processing blocks occurs, by virtue of conduction of the diode D1, a path in which a current placed under current limiting flows is provided in a case where overvoltage is applied to the communication output terminal DOUT1 (IC1). Accordingly, a voltage exceeding a withstand voltage is prevented from being applied to the INV2 as an output element, and the INV2 is protected against destruction.

According to the second embodiment of the present invention, destruction of the output element of the communication circuit can be prevented when the potential difference occurs between the measurement-and-processing blocks, by interposedly providing the resistor for protection between the communication output terminal and the communication input terminal of the measurement-and-processing blocks and interposedly providing the diode for voltage clamping.

### Third Embodiment

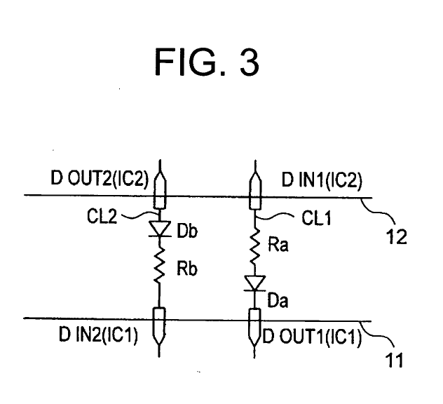

Referring now to FIG. 3, there is shown a circuit diagram of a battery cell voltage measurement device according to a third embodiment of the present invention. Although the third embodiment is generally in line with the first embodiment of FIG. 1 or the second embodiment of FIG. 2, diodes Da and Db are provided in series with the resistors Ra, Rb for protection, respectively. An anode of the diode Da is connected to an end of the resistor Ra. A cathode of the diode Da is connected to the communication output terminal DOUT1 (IC1). Likewise, an anode of the diode Db is connected to the communication output terminal DOUT2 (IC2), and a cathode of the diode Db to an end of the resistor Rb.

In this circuit configuration, when a voltage at the communication output terminal DOUT1 (IC1) of the lower-voltage-side measurement-and-processing block 11 becomes larger than a voltage at the communication input terminal DIN1 (IC2) of the higher-voltage-side measurement-and-processing block 12, then the diode Da enters a state of non-conduction to prevent a reverse current, thereby ensuring that the voltage exceeding the withstand voltage is not applied from the side of the lower-voltage-side measurement-and-processing block 11 to the circuit elements of the input-side communication circuit of the measurement-and-processing block 12, so that the destruction of the circuit elements is prevented.

Similarly, when the voltage at the communication input terminal DIN2 (IC1) of the lower-voltage-side measurement-and-processing block 11 becomes larger than the voltage at the communication output terminal DOUT2 (IC2) of the higher-voltage-side measurement-and-processing block 12, then the diode Db enters a state of non-conduction to prevent a reverse current, thereby a voltage exceeding the withstand voltage is not applied from the side of the lower-voltage-side measurement-and-processing block 11 to the circuit elements of the output side of the communication circuit of the higher-voltage-side measurement-and-processing block 12, so that destruction of the circuit elements is prevented.

The diodes Da and Db are connected in series with the resistors Ra and Rb, respectively, and yet at positions different from each other. Specifically, the diode Da is connected at a position closer to the output element (inverter INV1) of the measurement-and-processing block 11. The diode Db is connected at a position closer to the output element of the measurement-and-processing block 12 (an inverter not shown that corresponds to the inverter INV1). This is for the purpose of preventing a stray capacitance of the diode from affecting the communication speed when a current of a signal transmitted via the communication lines CL1 and CL2 are small according to design considerations.

The battery cell voltage measurement device according to the above-described exemplary embodiments of the present invention supports voltage level shifting functionality that has been mentioned in the introductory discussion of known inventions. The battery cell voltage measurement device includes a voltage level shifter 113 that performs voltage level shifting for the indication signal so that content of the indication signal conforms to the higher-voltage-side measurement-and-processing block.

As has been discussed in the foregoing in detail, according to the present invention, due to an inrush current occurring when connecting the battery cell voltage measurement device to a battery pack, a potential difference of a connecting portion between an upstream IC (i.e., the higher-voltage-side measurement-and-processing block) and a downstream IC (i.e., the lower-voltage-side measurement-and-processing block) may become large. In such a case, the communication lines and circuits connecting the upstream and downstream ICs can be protected against transient voltage change occurring between the measurement-and-processing blocks so that damage to the communication lines and circuits is prevented.

While the invention has been described in terms of specific embodiments, it will be understood by those skilled in the art that various modifications may be made therein without departing from the spirit and scope of the invention. Also, the terms and expressions which have been employed in this specification are used for description and not for limitation, there being no intention in the use of such terms and expressions of excluding equivalents of the features shown and described or portions thereof. Accordingly, the scope of this invention is only defined and limited by the following claims and their equivalents.

What is claimed is:

1. A battery cell voltage measurement device for a battery pack constructed of battery cells that are connected in series with each other, comprising:
(a) measurement-and-processing blocks that are connected to each other via a communication line, provided for corresponding each of the battery cells, and configured to measure a terminal voltage of the corresponding each of the battery cells, monitor a state of the corresponding each of the battery cells, generate an indication signal indicative of a result of monitoring of the corresponding each of the battery cells, perform voltage level shifting of the indication signal on a per-block basis, and transmit the voltage-level-shifted indication signal to a neighboring one of the measurement-and-processing blocks;
(b) a controller connected to one of the measurement-and-processing blocks via the communication line so as to control the measurement-and-processing blocks, and configured to receive the voltage-level-shifted indication signal sent from the measurement-and-processing block connected to the controller; and
(d) a resistor for protection provided on the communication line, the resistor for protection being configured to protect circuit elements of a communication circuit of the measurement-and-processing blocks from malfunction in a case where a potential difference occurs in a connection between the measurement-and-processing blocks adjacent to each other.

2. The battery cell voltage measurement device as set forth in claim 1, further comprising a diode for voltage clamping provided between a supply terminal and an output terminal of an output element of the measurement-and-processing block that sends the indication signal to the neighboring measurement-and-processing block connected via the communication line.

3. The battery cell voltage measurement device as set forth in claim 2, wherein a diode for reverse current prevention is provided in series with the resistor for protection so as to prevent a reverse current in a case where a voltage at a communication terminal of the measurement-and-processing block of a lower-voltage side becomes larger than a voltage of a communication terminal of the measurement-and-processing block of a higher-voltage side connected via the communication line to the lower-voltage side.

4. The battery cell voltage measurement device as set forth in claim 3, wherein the diode for reverse current prevention is closer to the output element of the measurement-and-processing block than the resistor for protection is.

5. The battery cell voltage measurement device as set forth in claim 4, wherein a zener diode for protection is provided between the communication output terminal and a GND terminal of the measurement-and-processing block.

6. The battery cell voltage measurement device as set forth in claim 5, wherein the controller is configured to output an instruction, signal for equalizing the terminal voltages of all the battery cells to the measurement-and-processing block connected to the controller, the measurement-and-processing blocks each perform voltage level shifting of the received instruction signal on a per-block basis, and transmit a voltage-level-shifted instruction signal to respective neighboring measurement-and-processing blocks via the communication line.
